(19) United States
(12) Patent Application Publication
(10) Pub. No.: US 2026/0209986 A1
(43) Pub. Date: Jul. 23, 2026

(54) SUSPENDED SAMPLE GROWTH DEVICE FOR IMAGING APPLICATIONS

(71) Applicant: The Regents of the University of California, Oakland, CA (US)

(72) Inventors: Tamir Gonen, Los Angeles, CA (US); Cody Gillman, Oakland, CA (US)

(21) Appl. No.: 19/138,851

(22) PCT Filed: Dec. 14, 2023
(86) PCT No.: PCT/US2023/084140

§ 371 Date: Jun. 13, 2025

Related U.S. Application Data
(60) Provisional application No. 63/387,479, filed on Dec. 14, 2022.

(51) Int. Cl. C30B 7/08; C30B 7/02; G01N 1/28; G01N 1/42

(52) U.S. Cl. CPC C30B 7/08; C30B 7/02; G01N 1/42; G01N 1/2813

(57) ABSTRACT

An apparatus and associated systems and methods for suspended drop crystallization for imaging applications. Unlike more traditional methods, suspended drop crystallization involves disposition of a sample directly on an electron microscopy grid without any additional support layers. The grid is then suspended within an incubation pod that allows for vapor diffusion to occur from both sides of the suspended drop. Windows within the incubation pod allow for monitoring of crystal growth. Once crystals have formed, the grid can be removed and utilized for crystallography data acquisition.

### CROSS-REFERENCE TO RELATED APPLICATIONS

This application claims the benefit of and priority to U.S. Provisional Patent Application No. 63/387,479, filed Dec. 14, 2022, the entire contents of which is incorporated by reference herein.

### STATEMENT REGARDING FEDERALLY SPONSORED RESEARCH

This invention was made with government support under HDTRA12110004 awarded by the U.S. Department of Defense, Defense Microelectronics Activity, and GM136508 awarded by the National Institutes of Health. The government has certain rights in the invention.

### BRIEF DESCRIPTION OF THE DRAWINGS

Various objects, features, and advantages of the disclosure can be more fully appreciated with reference to the following detailed description when considered with the following drawings.

FIGS. 1A-1F show multiple views and example dimensions of an apparatus for crystallography, in accordance with some aspects of the disclosure.

FIGS. 2A-2D show multiple views and example dimensions of different parts of the apparatus of FIG. 1, in accordance with some aspects of the disclosure.

FIGS. 3A-3D show multiple views and example dimensions of a modular system for crystallography that can be used with the apparatus of FIG. 1, in accordance with some aspects of the disclosure.

FIGS. 4A-4C show multiple views and example dimensions of a fixed system for crystallography that can be used with the apparatus of FIG. 1, in accordance with some aspects of the disclosure.

FIG. 5 shows an example process for crystallography that can be performed using the apparatus of FIG. 1, in accordance with some aspects of the disclosure.

FIG. 6 shows another example process for crystallography that can be performed using the apparatus of FIG. 1, in accordance with some aspects of the disclosure.

FIGS. 7A-7J show various illustrations and data that are associated with experimentation using the apparatus of FIG. 1 for an example soluble protein sample, Proteinase K, in accordance with some aspects of the disclosure.

FIGS. 8A-8C show various illustrations and data that are associated with experimentation using the apparatus of FIG. 1 for an example membrane protein sample, AmtB, in accordance with some aspects of the disclosure.

FIG. 9 shows an overview of some common sample preparation issues that can be solved using the apparatus of FIG. 1, in accordance with some aspects of the disclosure.

FIGS. 10A-10B show additional illustrations and data that are associated with experimentation using the apparatus of FIG. 1 for another example Proteinase K sample, in accordance with some aspects of the disclosure.

FIGS. 11A-11D show various illustrations and data that are associated with experimentation using the apparatus of FIG. 1 for additional example sample types, Catalase and M^{pro}, in accordance with some aspects of the disclosure.

### DETAILED DESCRIPTION

As the size of crystals and associated atomic and molecular structures studied for various medical and industrial purposes continues to decrease, the ability to handle samples carefully without damage becomes more and more important. In some existing systems and apparatuses used in crystallography, excessive handling (e.g., transferring) of crystals can be required, thereby introducing potential failure points before obtaining data from the crystals. Some existing systems and apparatuses used in crystallography also can only be used in certain configurations, such as in hanging drop or sitting drop configurations (vapor diffusion). Moreover, many existing systems for holding samples (e.g., well plates) come with a fixed quantity of receptacles (e.g., 12 receptacles, 24 receptacles, etc.) and are not expandable.

The systems, methods, and apparatuses/devices disclosed herein can be used for suspended drop crystallization using support-free grids. Suspended drop crystallization can provide advantages regarding sample preparation for imaging applications, where handling of the sample before obtaining data can be significantly reduced and/or entirely eliminated. Moreover, the original orientation of the crystal can be preserved, and the need for blotting can be bypassed. The technology described herein can be used for microcrystal electron diffraction (“MicroED”) as well as other similar and/or overlapping applications including cryogenic electron microscopy (CryoEM), electron crystallography, X-ray crystallography (e.g., using in-house, synchrotron, or x-ray free electron laser facility (XFEL) sources), and crystallography more generally. Various types of electron microscopes (e.g., transmission electron microscopes (TEM), etc.) can be used to obtain data (e.g., image data, light intensity data, etc.) from samples grown using the technology described herein.

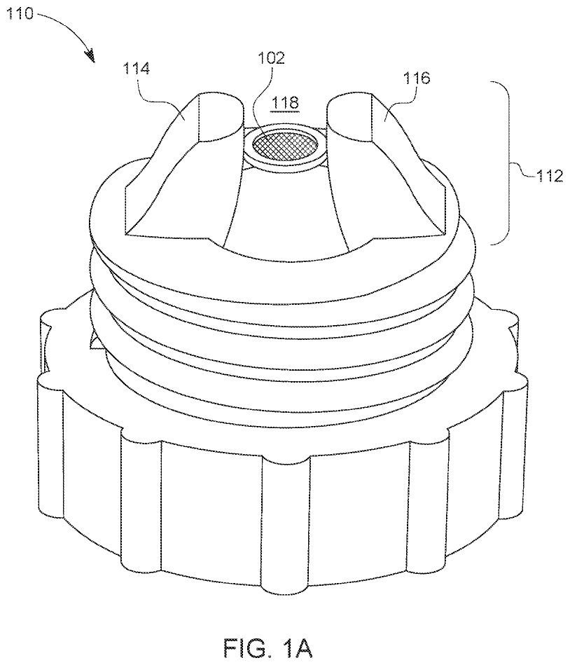

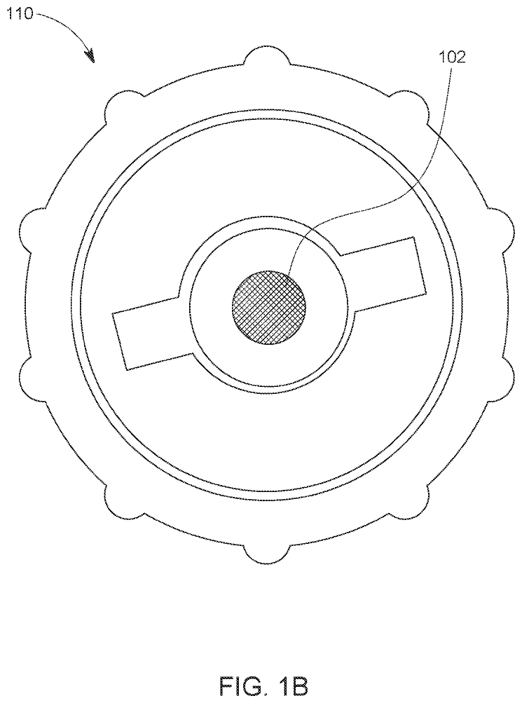

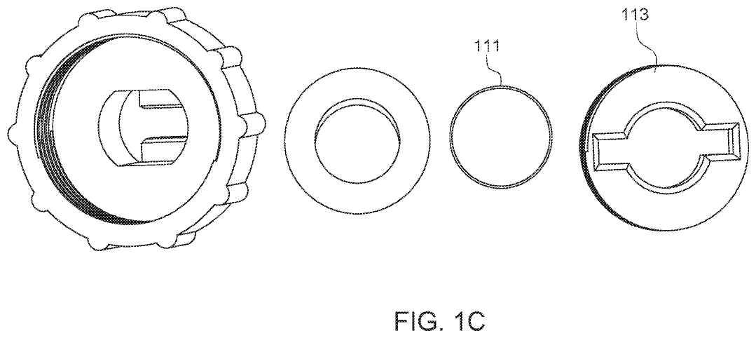

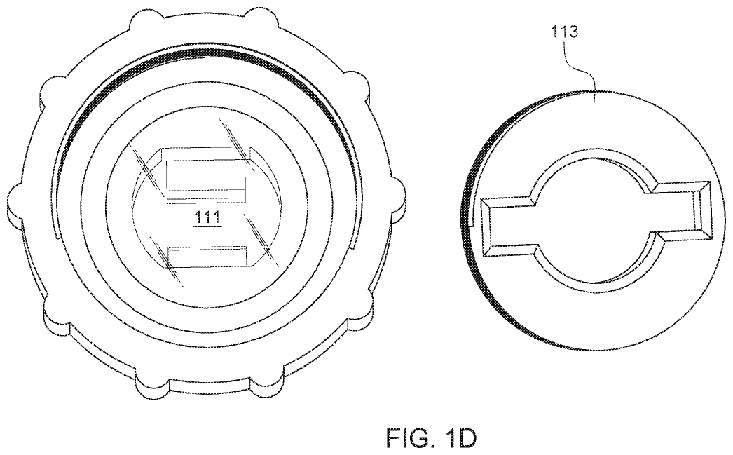

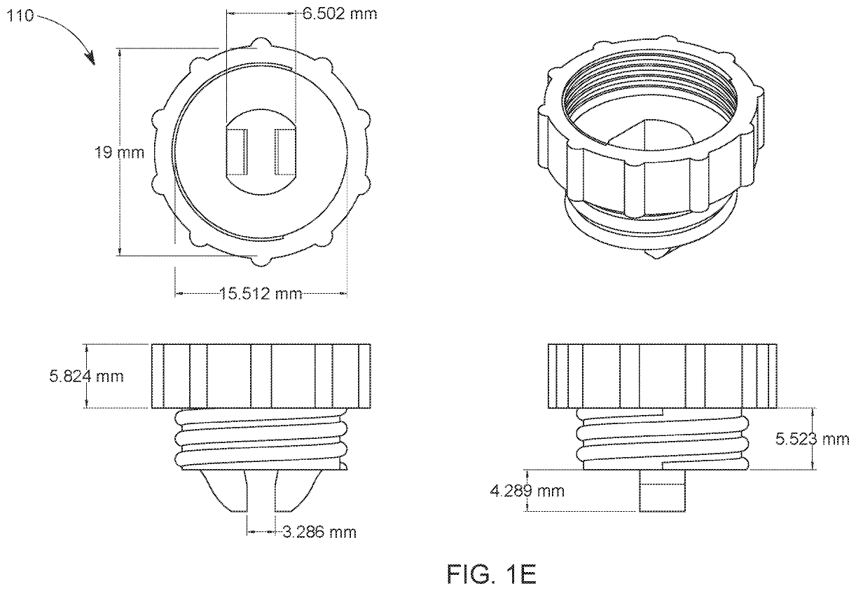

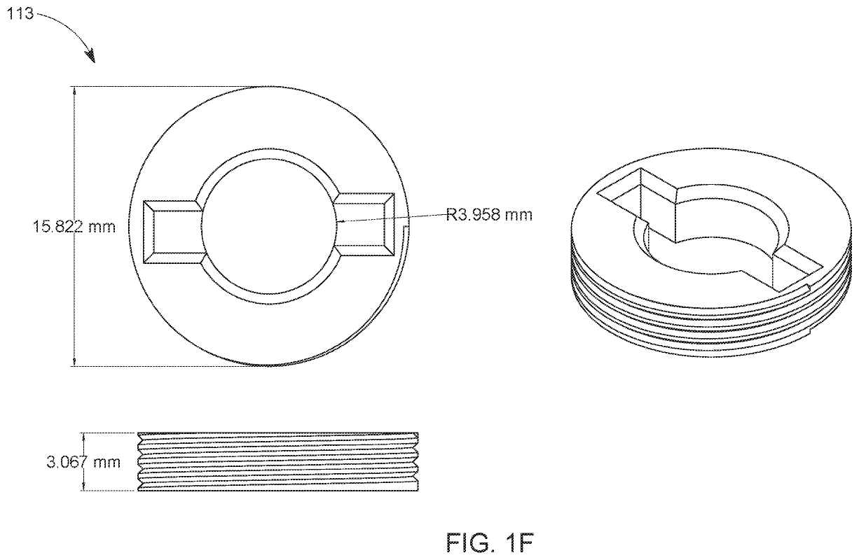

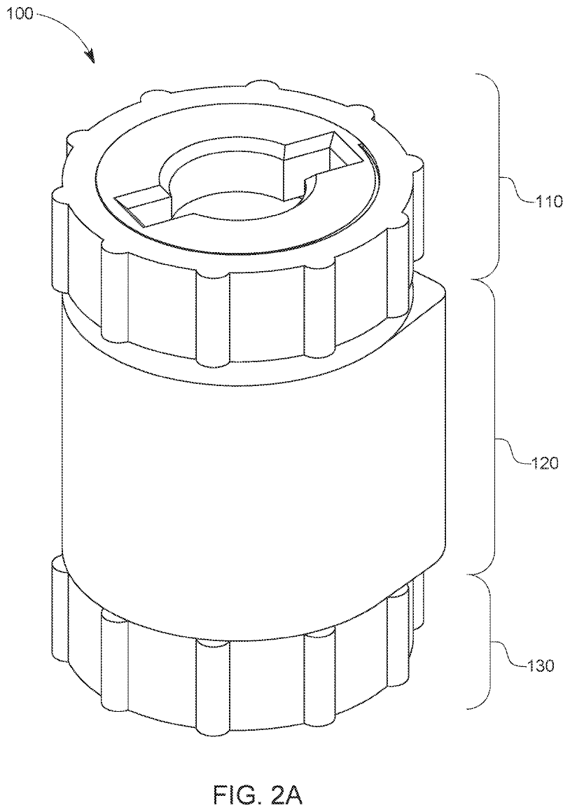

FIGS. 1A-1F show multiple different views as well as example dimensions associated with a screw cap piece 110 of an incubation pod 100 used for crystallography. As shown in FIG. 1A, the screw cap piece 110 can include a bridge structure 112 for securing a grid 102. The grid 102 can be various different types of grids for disposing a sample on, such as various types of electron microscopy (EM) grids. The grid 102 can be formed of copper material and/or other similar suitable materials and/or coatings. The grid 102 can generally be formed as a mesh-like structure with a plurality of openings formed within the grid 102. In some examples, the grid 102 can be formed of gold material with a lower mesh count (e.g., 50-200 mesh) to suspend crystallization drops during longer incubation periods because gold is chemically inert (e.g., as opposed to copper grids). The bridge structure 112 is not continuous, but rather can include a first bridge portion 114 and an opposing second bridge portion 116 with a gap 118 formed between the first bridge portion 114 and the second bridge portion 116. The grid 102 can be dimensioned such that it can be secured between the first bridge portion 114 and the second bridge portion 116 in the gap 118 to complete the bridge. When secured, an outer surface (e.g., along the circumference of the grid) of the grid 102 contacts the first bridge portion 114 and the second bridge portion 116, but a top surface and a bottom surface of the grid 102 do not contact the first bridge portion 114 and the second bridge portion 116.

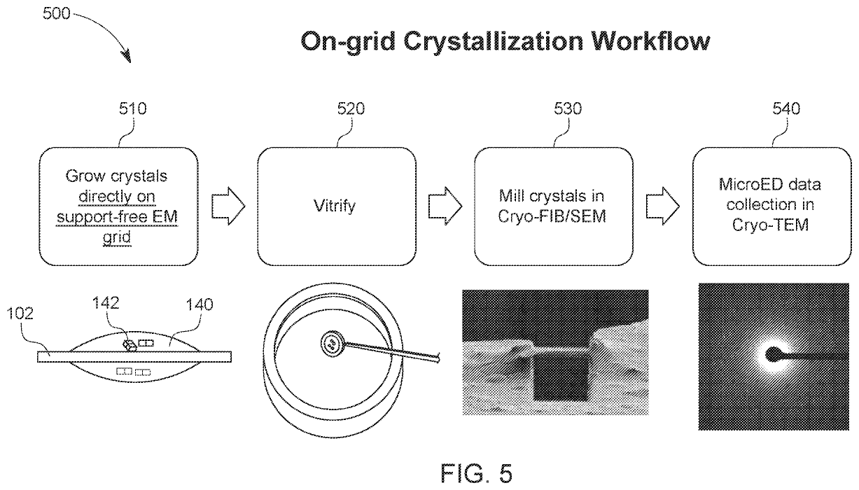

Due to this design of the screw cap piece 110, a sample can be disposed on the grid 102 in a suspended drop configuration (as opposed to hanging drop or sitting drop), where the sample hangs on the grid 102 so as to be free on all sides except at the point of contact by the grid 102 on the edges. As shown for example in FIG. 5, a sample 140 disposed on the grid 102 can extend both above the top surface of the grid 102 and below the bottom surface of the grid 102 after being disposed on the grid. Also, due to this design screw cap piece 110, the sample 140 can be disposed (e.g., pipetted) onto either the top surface or the bottom surface of the grid 102, since both the top surface and the bottom surface of the grid 102 are exposed. In some examples, the sample can be mixed with mother liquor. Vapor diffusion can therefore occur on both sides of the deposited sample sphere which is suspended from the grid 102.

FIG. 1B shows a surface of the screw cap piece 110 opposite the bridge structure 112 for securing the grid 102. As shown, this surface of the screw cap piece 110 includes an opening and a cavity, as well as a passage through which the grid 102 is exposed. FIGS. 1C and 1D show a window 111 and a coverslip tightening screw 113 for the screw cap piece 110. The coverslip tightening screw 113 can be fastened within the screw cap piece 110 to secure the window 111 within the screw cap piece 110. A light microscope can then be used to see the sample disposed on the grid 102 through the window 111. The window 111, in some examples, can be ultraviolet (UV) transparent so imaging with UV light is possible. The window 111 can also be made out of any material that would allow visualization without having to open the screw piece 110 (e.g., by unfastening the coverslip tightening screw 113).

FIGS. 1E and 1F show example dimensions associated with the screw cap piece 110 and the coverslip tightening screw 113, respectively. Notably, as shown, a distance between the first bridge portion 114 and the second bridge portion 116 can be between 3 millimeters and 3.5 millimeters, in some examples. Likewise, a height of the screw cap piece 110 can be between 13 millimeters and 20 millimeters, a height of the bridge structure 112 can be between 4 millimeters and 5 millimeters, and a width of the screw cap piece 110 can be between 15 millimeters and 25 millimeters, in some examples. Moreover, a height of the coverslip tightening screw 113 can be between 2.5 millimeters and 4 millimeters, and a width of the coverslip tightening screw 113 can be between 14 millimeters and 18 millimeters, in some examples. These specific dimensions can provide advantages in different crystallography applications.

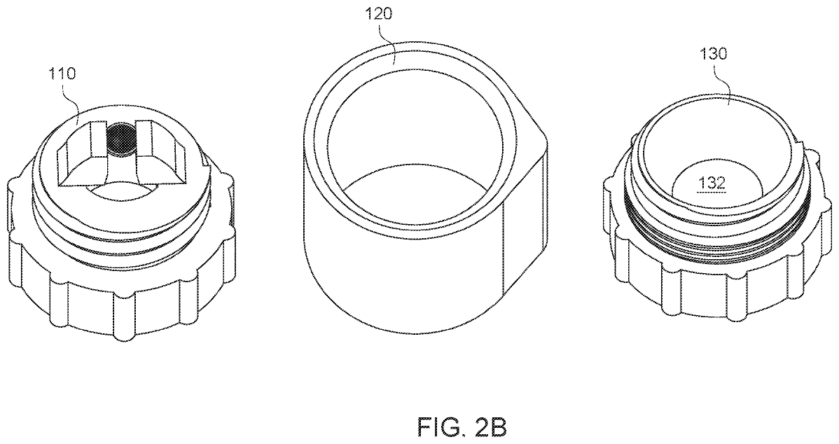

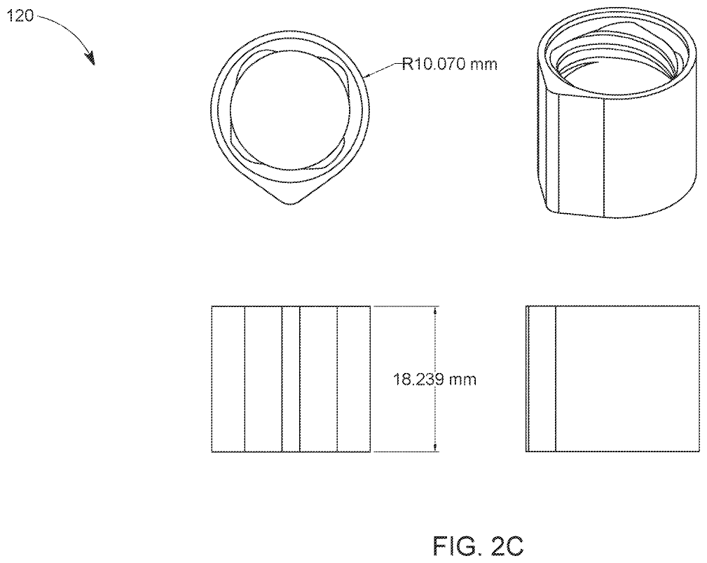

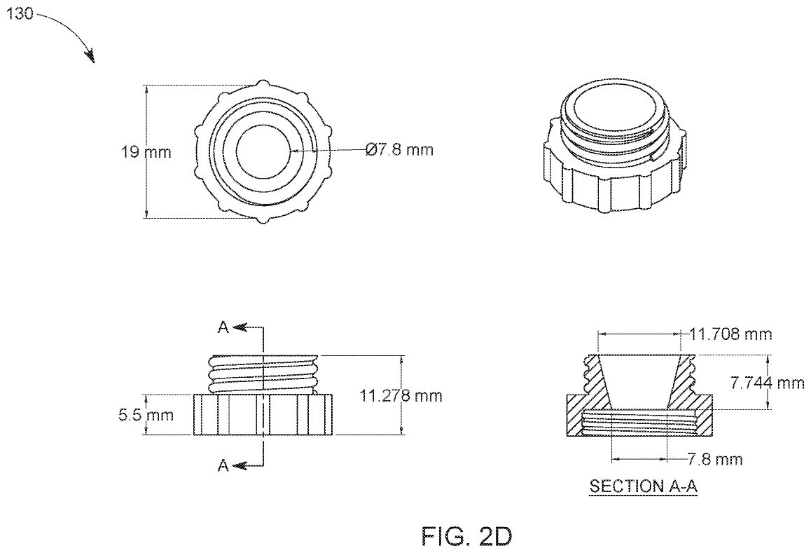

FIGS. 2A-2D show additional pieces of the incubation pod 100, including a bottom well screw piece 130 and a joiner piece 120 of the incubation pod 100, as well as example dimensions associated with the bottom well screw piece 130 and the joiner piece 120. The bottom well screw piece 130 includes a well 132 that is formed within the bottom well screw piece 130. The bottom well screw piece can also include a second window similar to the window 111 to allow for viewing into the incubation pod 100. The joiner piece 120 includes threads for securing the screw cap piece 110 and the bottom well screw piece 130 to the joiner piece 120 to complete assembly of the incubation pod 100. FIG. 2A, specifically, shows an example of the incubation pod 100 with all three pieces (the screw cap piece 110, the joiner piece 120, and the bottom well screw piece 130) secured together. FIG. 2B, specifically, shows an example of the incubation pod 100 with all three pieces separated. The incubation pod 100 and associated components can be designed electronically and manufactured additively (e.g., 3D-printed).

The example dimensions shown in FIG. 2C and FIG. 2D can provide advantages in different crystallography applications. As shown, a height of the joiner piece 120 can be between 15 millimeters and 20 millimeters and a width of the joiner piece 120 can be between 8 millimeters and 12 millimeters, in some examples. Also, a height of the bottom well screw piece 130 can be between 10 millimeters and 15 millimeters and a width of the bottom well screw piece 130 can be between 18 millimeters and 22 millimeters, in some examples. Moreover, the well 132 formed within the bottom well screw piece 130 can be shaped as a cone, where the radius of a first end of the cone closest to the joiner piece 120 is between 10 millimeters and 15 millimeters and a radius of a second end of the cone opposite the first end is between 5 millimeters and 10 millimeters, in some examples.

The different parts of the incubation pod 100 can be manufactured in various ways using various suitable materials. For example, the screw cap piece 110, the joiner piece 120, and the bottom well screw piece 130 can be designed using various types of computer-aided design (CAD) programs using various suitable parameters depending on the applications. The screw cap piece 110, the joiner piece 120, and the bottom well screw piece 130 can be 3D printed using any suitable types of 3D printer (e.g., a 3D printer with a 0.4 millimeter nozzle), a 0.1 millimeter layer height, and 40 millimeter s⁻¹ print speed, for example. The screw cap piece 110 and the joiner piece 120 can be formed using thermoplastic polyurethane (TPU) material and the bottom well screw piece 130 can be formed using co-polyester (CPE), for example. The joiner piece 120 can also be formed using co-polyester instead of thermoplastic polyurethane. The use of these specific materials and manufacturing parameters can provide advantages in terms of manufacturability and performance of the incubation pod 100 in many applications.

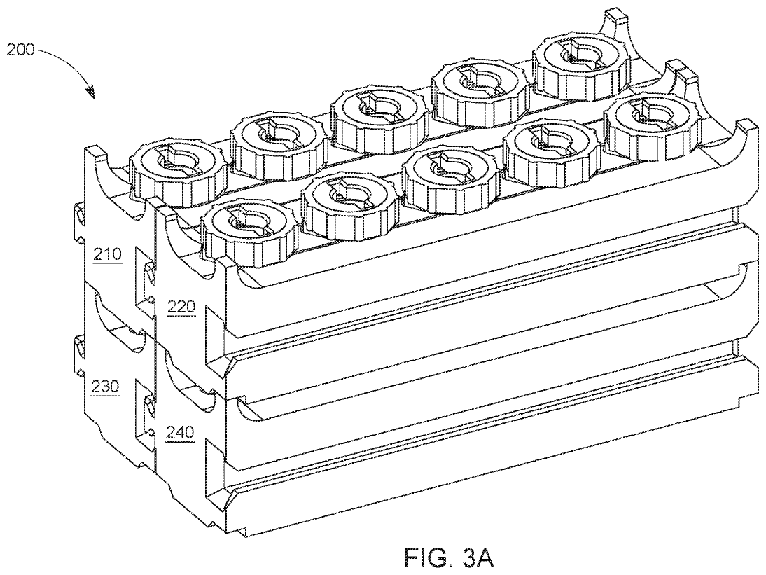

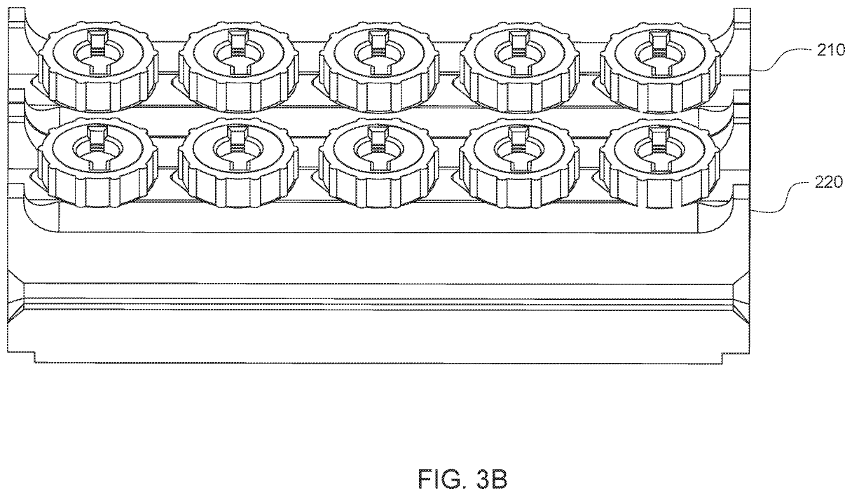

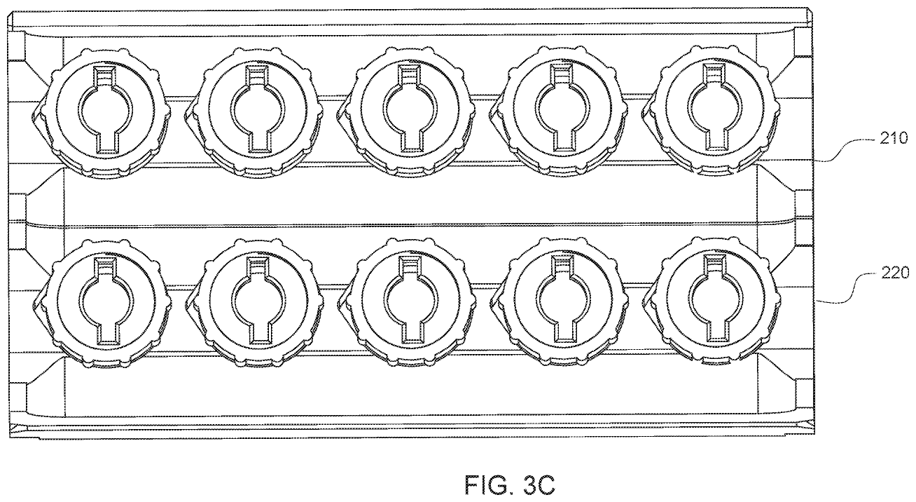

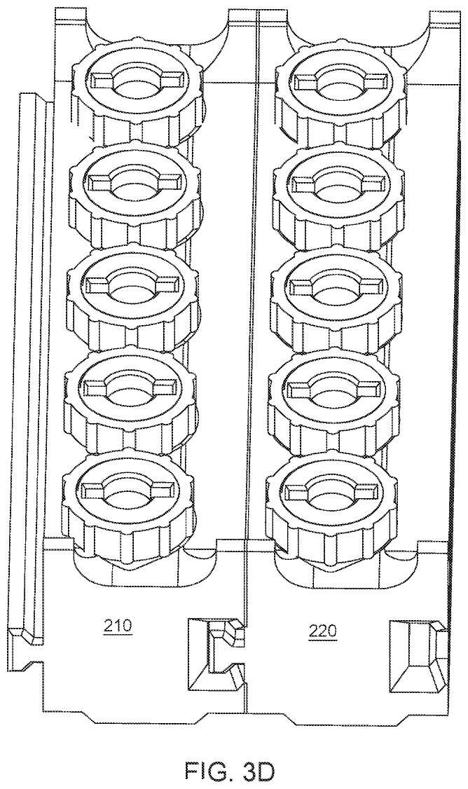

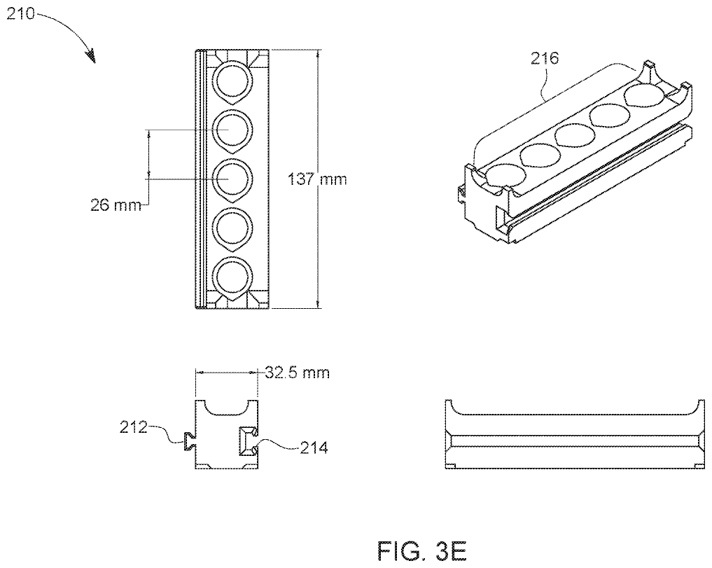

FIGS. 3A-3E show example implementations of a modular system 200 used for crystallography. The system 200 as shown in FIG. 3A, specifically, includes four interlocking racks: an interlocking rack 210, an interlocking rack 220, an interlocking rack 230, and an interlocking rack 240. Each of the interlocking rack 210, the interlocking rack 220, the interlocking rack 230, and the interlocking rack 240 includes a plurality of receptacles that each can hold an incubation pod such as the incubation pod 100 discussed above. The interlocking rack 210, the interlocking rack 220, the interlocking rack 230, and the interlocking rack 240 can be joined together as shown to form an array (tray). The interlocking rack 210, the interlocking rack 220, the interlocking rack 230, and the interlocking rack 240 can be joined side-to-side (horizontally) and/or top-to-bottom (vertically) as shown particularly in FIG. 3A. Interlocking racks such as the interlocking rack 210, the interlocking rack 220, the interlocking rack 230, and the interlocking rack 240 can be assembled in various modular configurations to provide various types and sizes of arrays. The interlocking or otherwise connecting of racks to from an array can be repeated ad infinitum. In some examples, each receptacle in the array can be used to screen a different condition to improve efficiency of sample screening, however various uses are contemplated and possible with this modular design.

The interlocking rack 210, the interlocking rack 220, the interlocking rack 230, and the interlocking rack 240 can be joined such that they are both connectable to and removable from each other in any suitable manner, including using the male and female interlocking pieces as shown in FIGS. 3A-3E and/or any other suitable connection means. While the examples shown in FIGS. 3A-3E are 5×1 interlocking racks, it will be appreciated that similar racks including any variable number of receptacles can be used in a similar fashion. As shown in FIG. 3E, the interlocking rack 210 can include a male interlocking piece 212 disposed on a first side of the interlocking rack 210 as well as a female interlocking piece 214 disposed on a second side of the interlocking rack 210 opposite the first side. Also, the interlocking rack 210 includes a plurality of receptacles 216 (in this example, 5 receptacles) that can each hold an incubation pod such as the incubation pod 100 discussed above. A length of the interlocking rack 210 cam be between 130 and 150 millimeters and a distance between the centers of each the plurality of receptacles 216 can be between 18 millimeters and 22 millimeters, in some examples. The interlocking rack 220, the interlocking rack 230, and the interlocking rack 240 can include similar or the same components and dimensions as the interlocking rack 210.

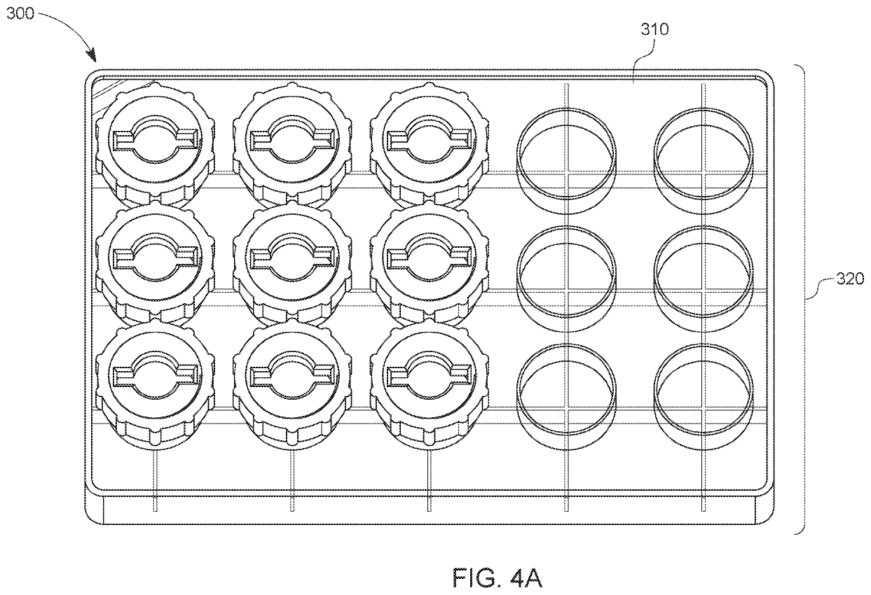

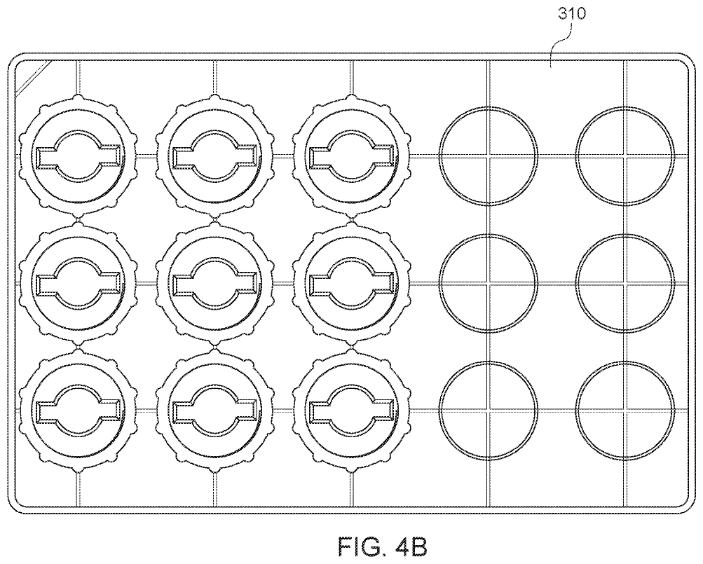

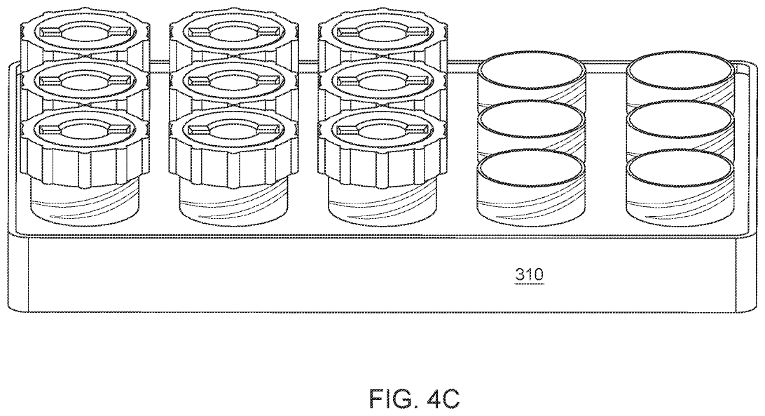

FIGS. 4A-4C example implementation of a fixed system 300 used for crystallography. The system 300 as shown includes a fixed size well plate 310 including a plurality of receptacles 320. Each of the plurality of receptacles 320 can hold an incubation pod such as the incubation pod 100 discussed above. While the well plate 310 is shown to include 15 receptacles arranged in a 5×3 configuration, any suitable number of receptacles can be included in the well plate 310 depending on the application. The system 300 can provide advantages in terms of ease of use in certain applications.

FIG. 5 is an illustration of a process 500 for on-grid crystallization that can be performed using an incubation pod such as the incubation pod 100 as detailed above. First, at 510, a sample 140 can be disposed on a support-free electron microscopy grid, such as the grid 102 of the incubation pod 100. The sample 140 can be disposed on the grid 102 in a suspended drop configuration as discussed above. Upon disposing the sample 140 on the grid 102, the sample 140 can be screened for crystal growth. Next, a crystal 142 in the sample 140 can be vitrified using a variety of suitable vitrification processes (e.g., frozen hydrating, etc.). Then, the crystal 142 can be used directly for imaging or, if needed, the crystal 142 can be milled (e.g., shaped) using a variety of suitable milling processes, such as using a focused ion beam-scanning (FIB-SEM) approach where the ion beam cuts into the crystal 142. Finally, data such as images and/or MicroED data can be collected from the crystal 142 using various suitable methods including using various types of electron microscopes and associated software (e.g., transmission electron cryomicroscopy (CryoTEM), which is sometimes referred to as Cryogenic electron microscopy (cryo-EM)), among other possible approaches to collecting data such as x-ray crystallography and/or other suitable methods. For x-ray analysis, the grid 102 can be mounted onto a goniometer, for example.

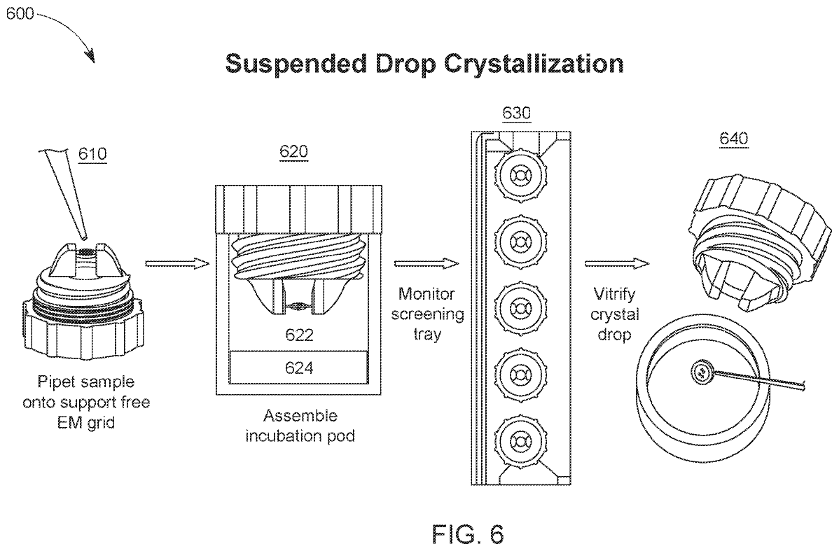

FIG. 6 is an illustration of a process 600 for suspended drop crystallization that can be performed using an incubation pod such as the incubation pod 100 as detailed above. First, at 610, a sample is pipetted onto a support-free electron microscopy grid (e.g., the sample 140 is pipetted onto the grid 102). The grid 102 can be secured between the first bridge portion 114 and the second bridge portion 116 of the screw cap piece 110, and the sample 140 can be pipetted onto the grid 102 in a suspended drop configuration as discussed above. Next, at 620, the full incubation pod 100 can be assembled by securing the joiner piece 120 to the screw cap piece 110, and securing the bottom well screw piece 130 to the joiner piece 120. When fully assembled, as shown in FIG. 6, the incubation pod 100 defines an incubation chamber 622 containing mother liquor 624. These first two steps 610 and 620 can be repeated for multiple different incubation pods (e.g., for screening different conditions) and then placed into a screening array such as the system 200 or the system 300 described above. Then, at 630, the screening array can then be monitored for crystal growth. A light microscope can be used along with UV fluorescence to view the samples through the window 111 disposed in the screw cap piece 110 to check for crystal growth, for example. Once crystals are found, the crystals can be vitrified at 640 using any of a variety of suitable vitrification processes (e.g., frozen hydrating using liquid ethane, liquid nitrogen, etc.), and then data can be collected form the crystals.

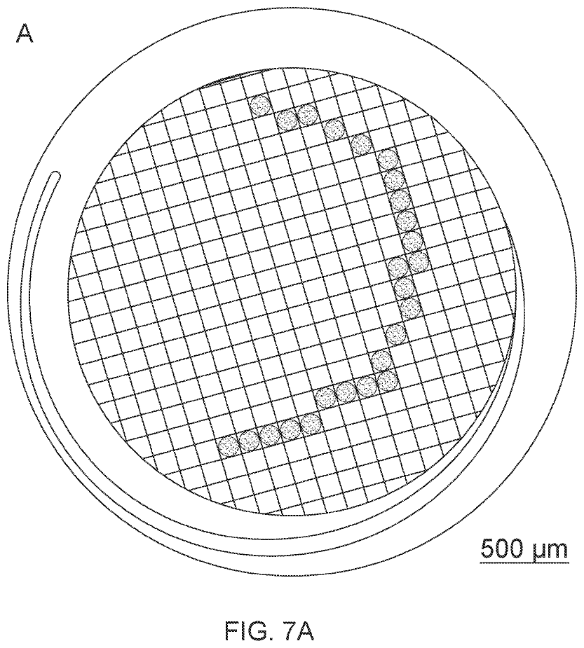

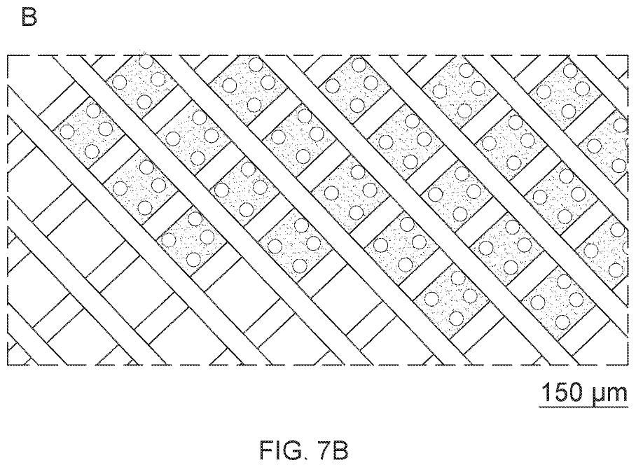

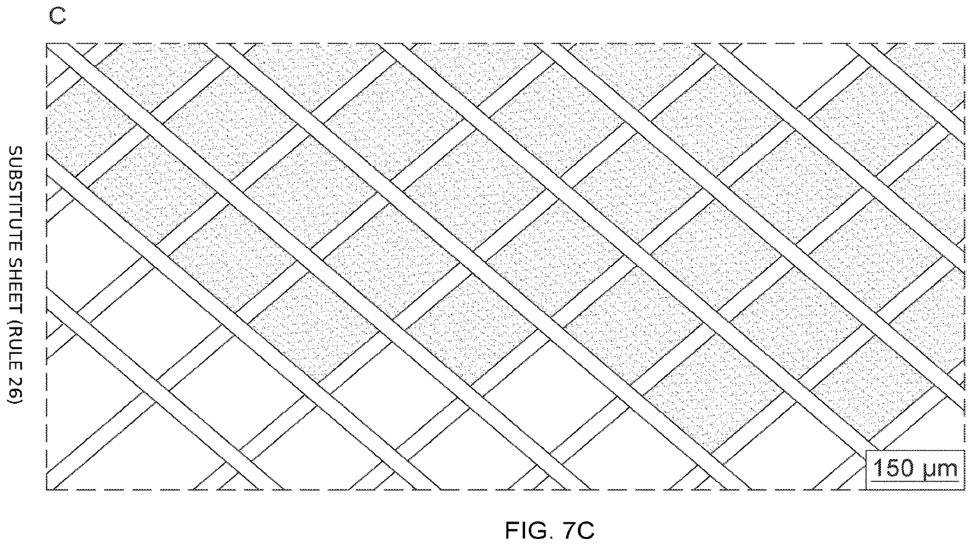

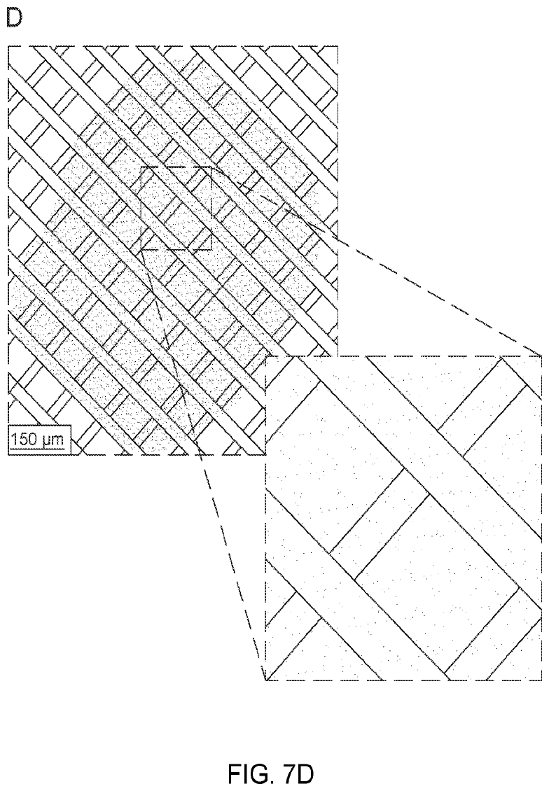

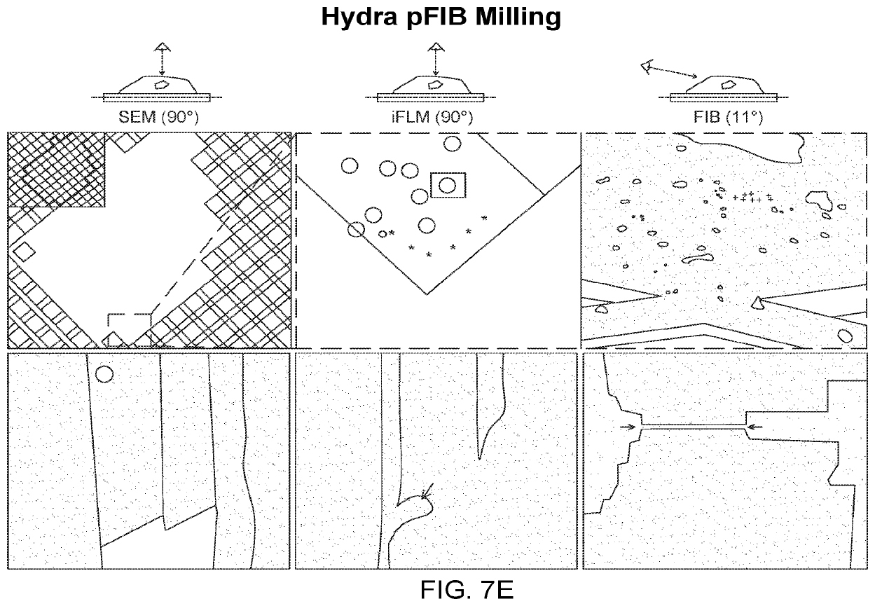

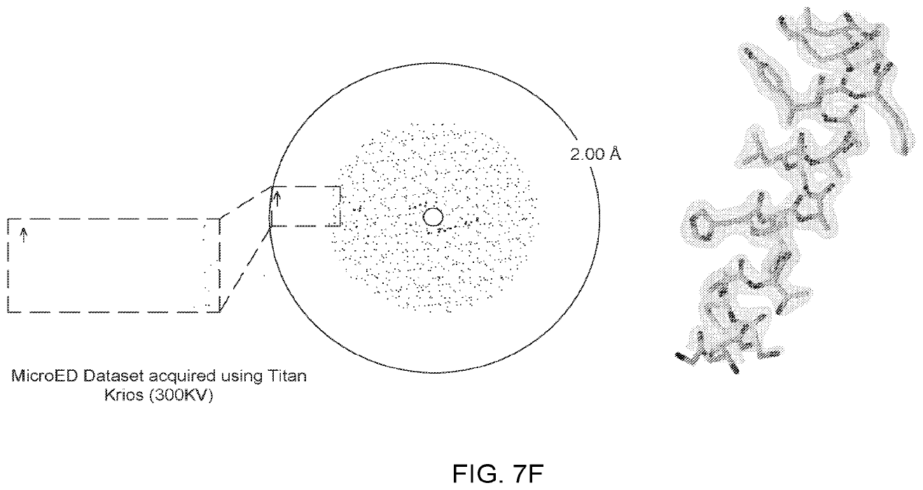

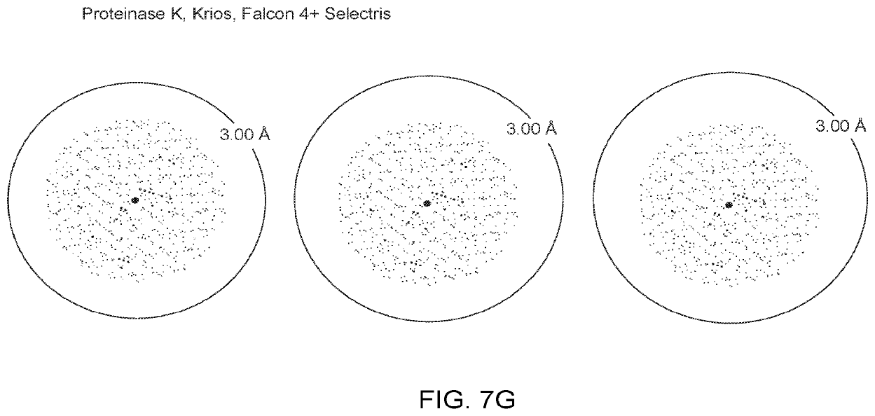

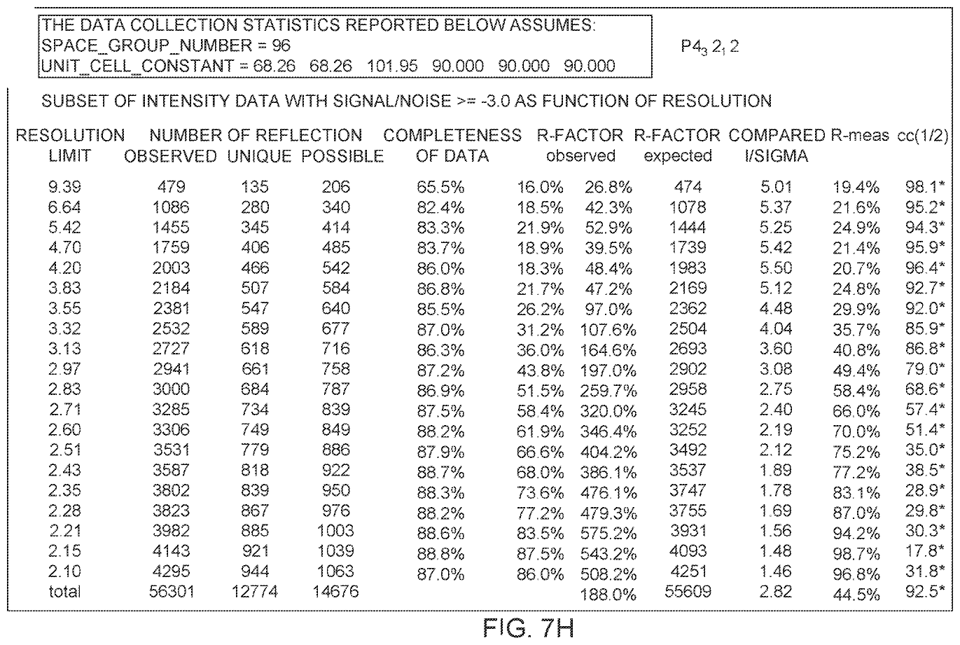

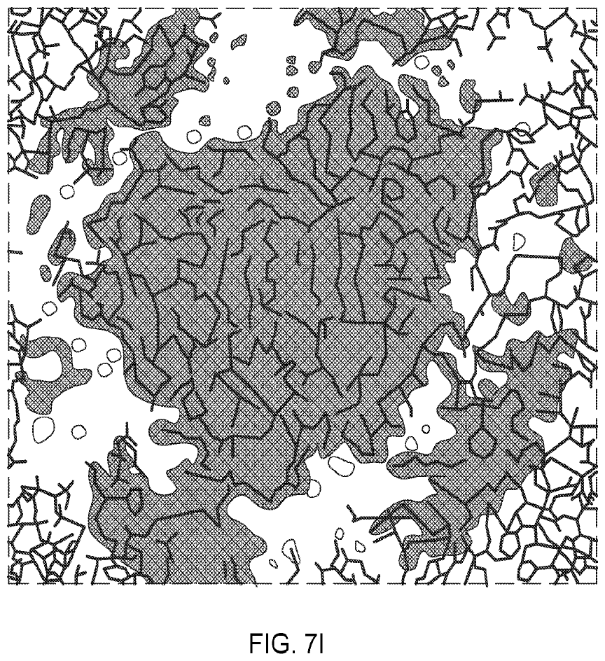

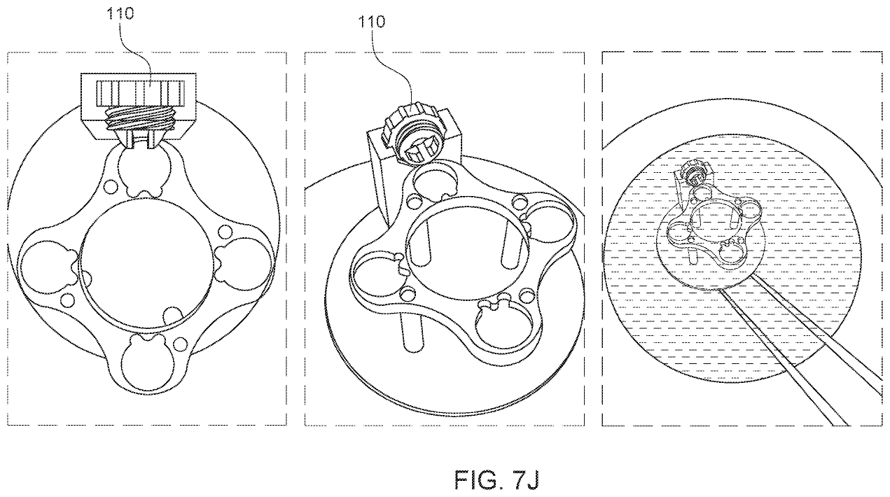

FIGS. 7A-7I show various illustrations and data associated with experimentation using the on-grid suspended drop screening tools described above (e.g., the incubation pod 100) with a Proteinase K sample as the sample 140. FIGS. 7A-7D show different images at different resolutions and contrasts of crystals grown on a grid from a suspended drop Proteinase K sample. FIG. 7E shows example imaging during the crystal milling process. In this particular example, hydra plasma focused ion beam scanning electron microscope (PFIB-SEM) is used to mill the crystals, with different beams projected at the crystal from different angles. FIGS. 7F-7H show example data collected during the processing of the Proteinase K sample. FIG. 7I shows an example crystal structure found by analyzing the Proteinase K sample. FIG. 7 shows an example of vitrification, where the grid 102 is removed from the screw cap piece 110 and dunked into a solution (e.g., ethane, liquid nitrogen, etc.) to freeze the crystals.

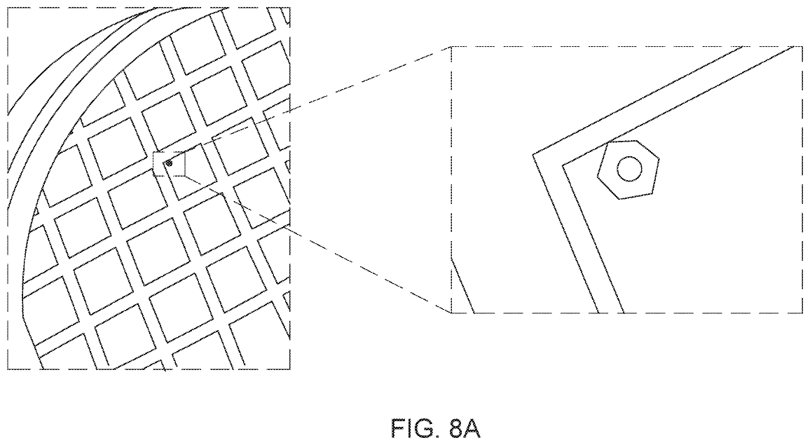

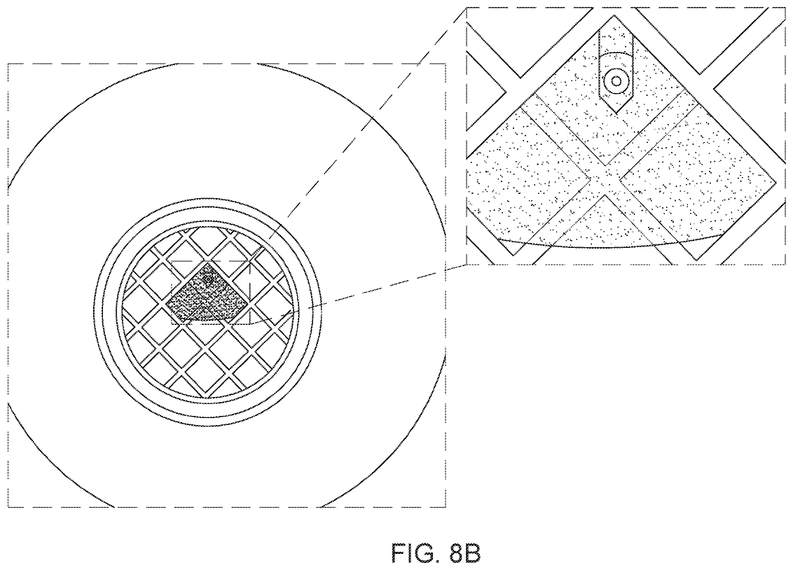

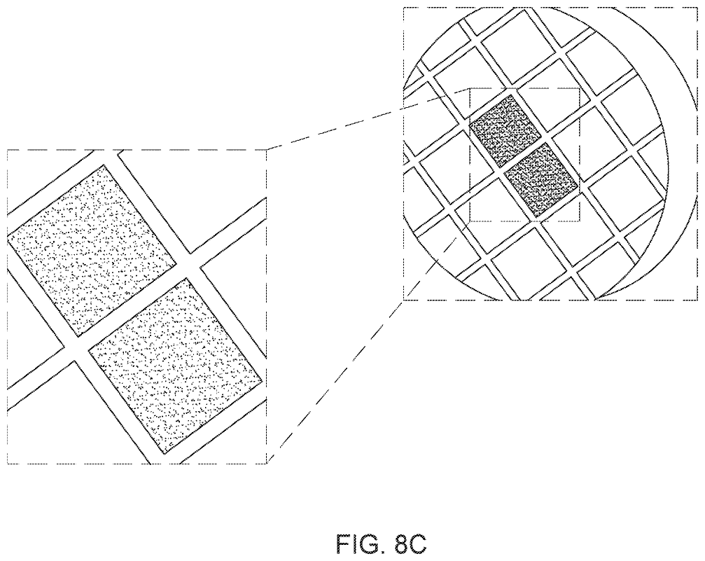

FIGS. 8A-8C show example illustrations associated with experimentation using the on-grid suspended drop screening tools described above (e.g., the incubation pod 100) with an ammonia transporter (AmtB) sample as the sample 140. During the experimentation, a mesh gold gilded grid was used as the grid 102. As can be seen from the illustrations provided in FIGS. 8A-8C, using the on-grid suspended drop screening tools described above, crystals were successfully grown on the grid 102 from the AmtB sample.

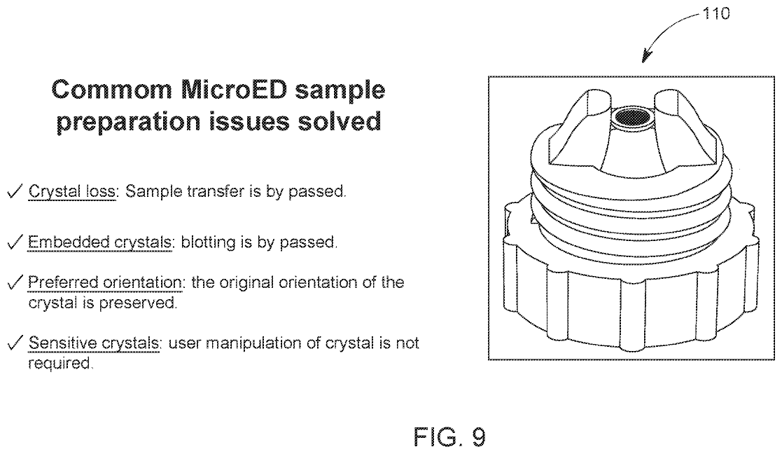

FIG. 9 provides an overview of some common sample preparation issues that can occur during MicroED and can be solved using the screw cap piece 110 of the incubation pod 100 as described above. Crystal loss can be eliminated or reduced since sample transfer can be bypassed using the incubation pod 100. Embedded crystals can also be provided to remove the need for blotting during the MicroED process. Also, the preferred, original orientation of the crystal 142 can be preserved. These and other factors make the incubation pod 100 disclosed herein particularly advantageous for applications involving various types of small and/or sensitive crystal structures because user manipulation of crystals is not required. Also included after FIG. 9 is an appendix containing slides from a presentation detailing the technology described in the present disclosure.

The modular apparatus (i.e., the incubation pod 100) described herein can be used for crystal growth directly on electron microscopy grids with any metal or using any surface or suspended without a support film. The grid 102 with the sample 140 can be placed on the fabricated holder (e.g., in the gap 118 between the first bridge portion 114 and the second bridge portion 116), and the screw cap piece 110 can be closed over a crystallization buffer in a custom designed bin (e.g., the interlocking rack 210). Windows above and below (e.g., the window 111) can allow for inspection of crystal growth without disturbing the sample 140. Multiple bins can be assembled into an array (e.g., like the system, 200) so that thousands of conditions could theoretically be screened. Once crystals grow, the incubation pod 100 can be opened, and the grid 102 can be taken out and frozen. The grid 102 can then be transferred onto a scanning electron microscope (SEM) with a focused ion beam for milling. Crystal lamella can thus be prepared, and the structures analyzed and solved by MicroED (e.g., software, etc.).

The approach described herein can minimize the handling of samples post crystal growth, maintain crystal integrity, streamline the sample preparation, and accelerate structure determination. The on-grid crystals can be used for any diffraction or imaging-based methods. Samples can be proteins, complexes, small molecules, materials like metal-organic frameworks (MOF) and natural products, and even entire cells and organelles that can be grown on the grid 102 for analysis. The structure determination and imaging can be done with synchrotrons and x-ray free electron laser facilities, in addition to light and electron microscopes.

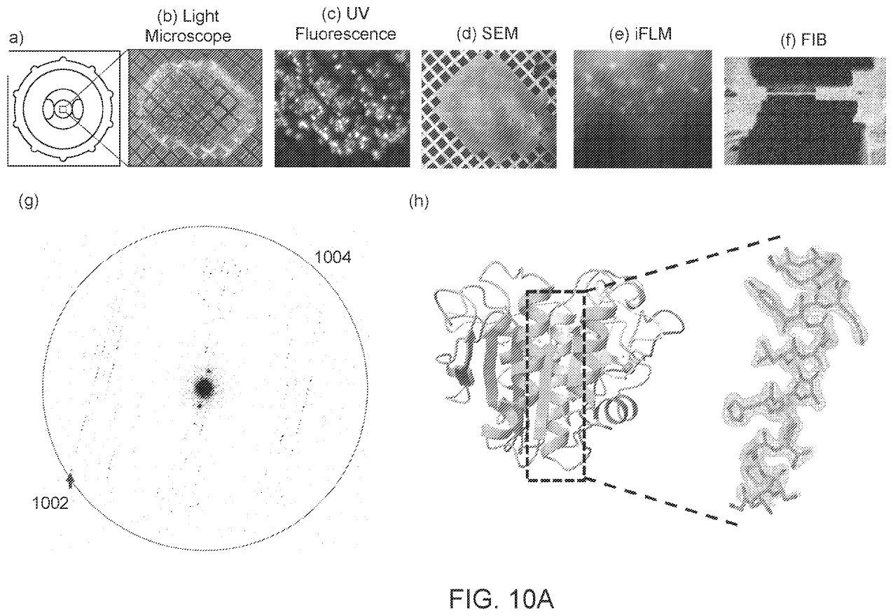

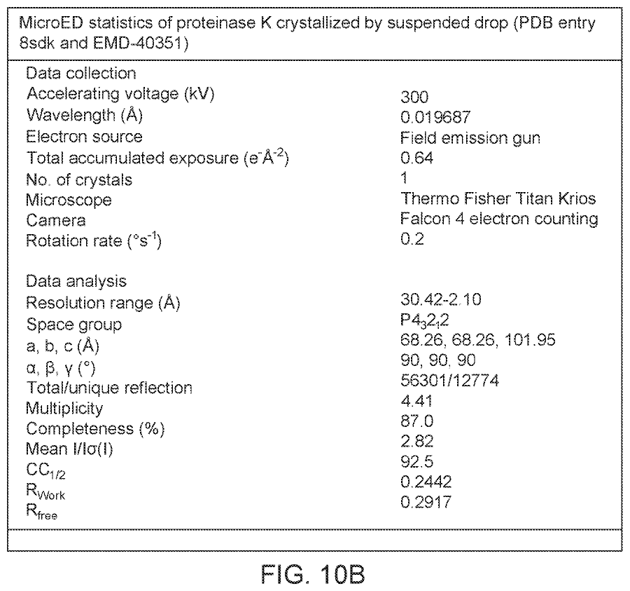

FIGS. 10A-10B show additional illustrations and data associated with experimentation using the on-grid suspended drop screening tools described above (e.g., the incubation pod 100) with a Proteinase K sample as the sample 140. In FIG. 10A, a suspended drop Proteinase K disposed on the grid 102 and viewed from the top of the incubation pod 100 through the window 111 is shown (a). Then, images of the suspended drop acquired using light microscopy (b) and UV fluorescence (c) are shown. A frozen suspended drop Proteinase K specimen was then loaded into the FIB-SEM and imaged normal to the grid surface by SEM (d) and by integrated fluorescence microscopy (iFLM) (e) with a 385 nanometer light-emitting diode (LED) to locate submerged crystals. Next, the targeted crystal site was milled into a 300 nanometer thick lamella using FIB (e.g., a xenon plasma beam) (f) and MicroED data was acquired from the crystal lamella (g). The highest resolution reflections in the MicroED are visible to 2.1 angstroms at location 1002 shown in FIG. 10A (the resolution ring 1004 is shown at 2.0 angstroms). Cartoon representations of the Proteinase K are also shown (h) with an N terminus and a C terminus. The 2mFₒ-DF_{c} map of a selected α-helix is highlighted, which was contoured at 1.5σ with a 2 angstrom carve. FIG. 10B shows a table of MicroED data associated with the suspended drop Proteinase K converted to standard crystallographic formats. The determined structure of Proteinase K determined based on this data matches other MicroED structures of Proteinase K determined from crystals handles using previous, more traditional MicroED sample preparation protocols.

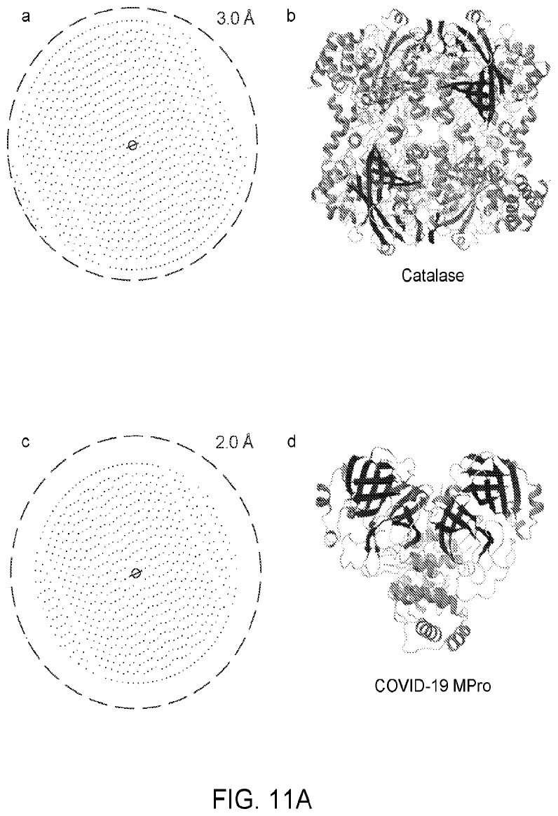

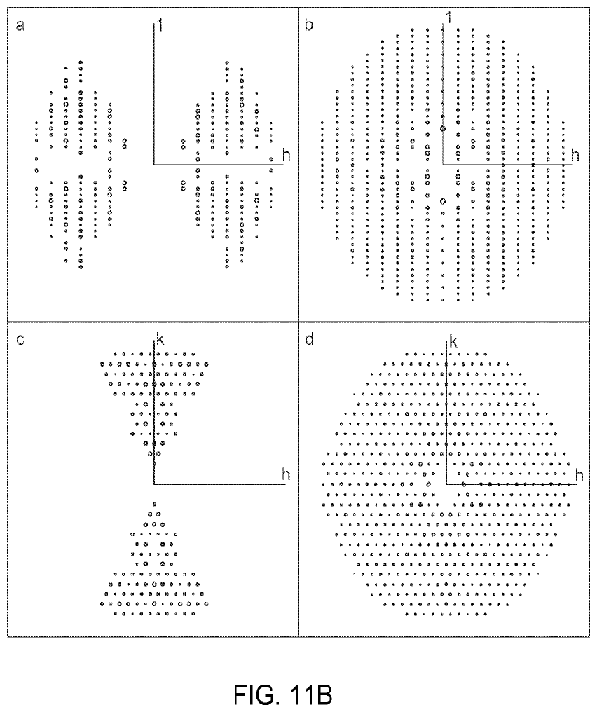

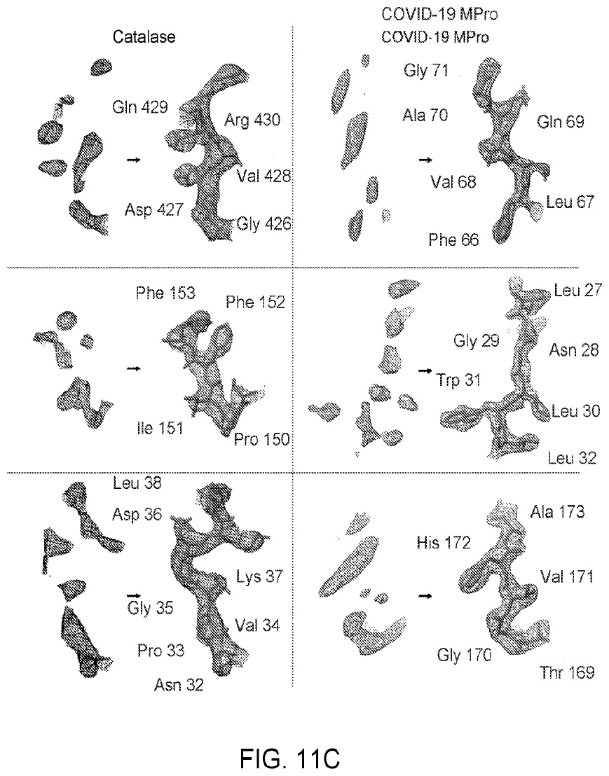

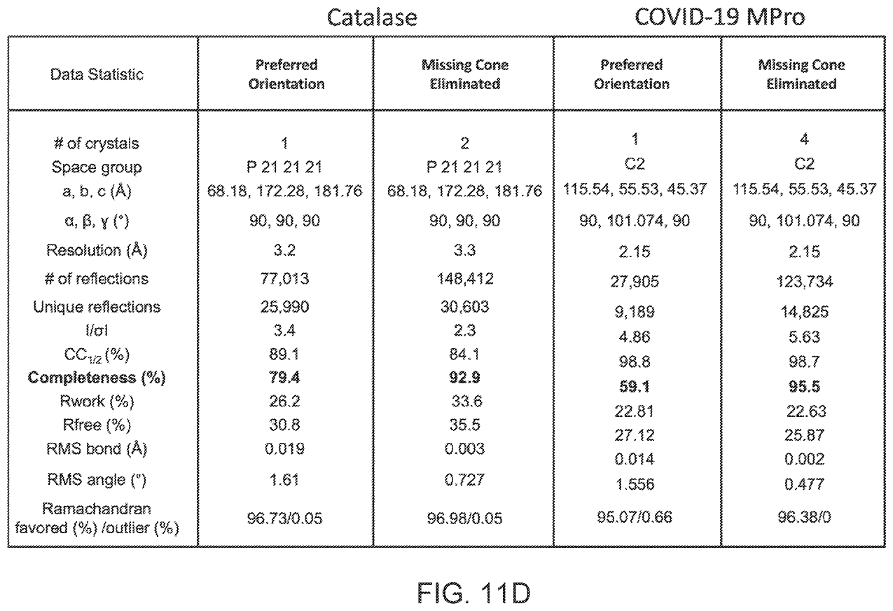

A technical challenge that can create several bottlenecks in the MicroED workflow is when crystals with plate-like morphologies recurrently adopt a preferential orientation on the electron microscopy grid, lying flat with one axis perpendicular to the support surface. Due to hardware restrictions in the transmission electron microscope, some MicroED experiments can be systematically limited as only one cone of reciprocal space is available for sampling, and every dataset acquired is missing the same cone of data. To address this issue, suspended drop crystals can be used to eliminate the missing cone of the crystal lattice and provide more complete datasets. FIGS. 11A-11D show illustrations and data associated with experimentation regarding eliminating the missing cone of a crystal lattice using Catalase and the COVID-19 main protease M^{pro} as the sample 140. This approach for obtaining the missing cone can be key for crystals that experience preferred orientations and resist structure determination.

FIG. 11A shows example MicroED data that can be collected from Catalase and M^{pro} samples using the incubation pod 100. Specifically, FIG. 11A shows an electron diffraction frame acquired from Catalase (a), a ribbon model of Catalase (b), an electron diffraction frame acquired from M^{pro} (c), and a ribbon model of M^{pro} (d). FIG. 11B illustrates the recovery of missing reflections in the MicroED datasets of both Catalase and M^{pro}. Specifically, FIG. 11B shows a 2D slice of observed reflections in the preferred orientation dataset viewed along the k-axis for Catalase (a), a 2D slice of observed reflections in the missing cone eliminated dataset viewed along the k-axis for Catalase (b), a 2D slice of observed reflections in the preferred orientation dataset viewed along the l-axis for M^{pro} (c), and a 2D slice of observed reflections in the missing cone eliminated dataset viewed along the l-axis for M^{pro} (d).

FIG. 11C shows several regions of both Catalase and M^{pro} that can exhibit significant density improvements upon completion of the reciprocal space. Specifically, FIG. 11C shows 2mFₒ-DF_{c} maps that are all contoured at 1.2σ and 2.0 angstrom carve. On the left side in each panel shown in FIG. 11C, the preferred orientation map density (uninterpretable density) is compared to that for the missing cone eliminated density (interpretable density) on the right side in each panel shown in FIG. 11C. FIG. 11D is a table showing processing statistics of Catalase preferred orientation crystal vs. missing cone merged data and statistics of M^{pro} preferred orientation crystal vs. missing cone merged data.

The present disclosure has described one or more aspects, and it should be appreciated that many equivalents, alternatives, variations, and modifications, aside from those expressly stated, are possible and within the scope of the invention.

1. An apparatus for suspended crystal or sample growth, comprising:
a screw cap piece for holding a grid, the screw cap piece comprising a first bridge portion and an opposing second bridge portion, wherein the grid is dimensioned to be secured between the first bridge portion and the second bridge portion such that an outer surface of the grid contacts the first bridge portion and the second bridge portion;
a bottom well screw piece comprising a well that is formed within the bottom well screw; and
a joiner piece comprising threads for securing the screw cap piece and the bottom well screw to the joiner.

2. The apparatus of claim 1, wherein the grid is further dimensioned such that, when secured between the first bridge portion and the second bridge portion, a top surface of the grid and a bottom surface of the grid do not contact the first bridge portion and the second bridge portion.

3. The apparatus of claim 1, further comprising a window disposed within the screw cap piece, wherein a sample disposed on the grid is visible through the window.

4. The apparatus of claim 3, further comprising a coverslip tightening screw that fastens within the screw cap piece to secure the window within the screw cap piece.

5. The apparatus of claim 3, wherein the window is ultraviolet (UV) transparent.

6. The apparatus of claim 3, further comprising a second window disposed within the bottom well screw piece, wherein the sample disposed on the grid is visible through the second window.

7. The apparatus of claim 1, wherein the screw cap piece is formed of a thermoplastic polyurethane material.

8. The apparatus of claim 1, wherein the joiner piece is formed of a co-polyester material.

9. The apparatus of claim 1, wherein the bottom well screw piece is formed of a co-polyester material.

10. A method for suspended drop crystal or sample growth, comprising:
securing a grid between a first bridge portion and a second bridge portion of a screw cap piece such that an outer surface of the grid contacts the first bridge portion and the second bridge portion;
disposing a suspended sample onto the grid;
screening crystal growth on the grid;
vitrifying the suspended sample on the grid; and
generating data that is indicative of a structure of the suspended sample.

11. The method of claim 10, further comprising:
securing the screw cap piece to a joiner piece; and
securing a bottom well screw piece comprising a well that is formed within the bottom well screw to the joiner piece.

12. The method of claim 10, wherein securing the grid between the first bridge portion and the second bridge portion of the screw cap piece comprises securing the grid between the first bridge portion and the second bridge portion of the screw cap piece such that a top surface of the grid and a bottom surface of the grid do not contact the first bridge portion and the second bridge portion.

13. The method of claim 10, wherein vitrifying the suspended sample grown on the grid comprises freezing the suspended sample by placing the grid in a freezing solution.

14. The method of claim 10, further comprising milling the suspended sample grown on the grid.

15. The method of claim 14, wherein milling the suspended sample grown on the grid comprises milling the suspended sample with a focused ion beam or a plasma focused ion beam.

16. The method of claim 10, wherein generating the data that is indicative of the structure of the suspended sample comprises using an electron microscopy, light microscopy, or x-ray crystallography.

17. A system for sample growth, comprising:
a first rack comprising a first plurality of receptacles; and
a second rack comprising a second plurality of receptacles, wherein the second rack is connectable to the first rack to form an array comprising the first plurality of receptacles and the second plurality of receptacles, and wherein the second rack is removable from the first rack;
wherein each of the first plurality of receptacles and the second plurality of receptacles are dimensioned to receive and hold an apparatus containing a sample.

18. The system of claim 17, wherein the apparatus containing the sample comprises:
a screw cap piece for holding a grid, the screw cap comprising a first bridge portion and an opposing second bridge portion, wherein the grid is dimensioned to be secured between the first bridge portion and the second bridge portion such that an outer surface of the grid contacts the first bridge portion and the second bridge portion;
a bottom well screw piece comprising a well that is formed within the bottom well screw; and
a joiner piece comprising threads for securing the screw cap and the bottom well screw to the joiner.

19. The system of claim 17, further comprising a third rack comprising a third plurality of receptacles, wherein the third rack is connectable to the first rack or the second rack, and wherein the third rack is removable from the first rack or the second rack.

20. The system of claim 17, wherein the first rack comprises a male interlocking piece disposed on a first side of the first rack and a female interlocking piece disposed on a second side of the first rack, the first side opposite the second side.
